(19) United States
(12) Patent Application Publication
(10) Pub. No.: US 2009/0237101 A1
(43) Pub. Date: Sep. 24, 2009

(54) METHOD FOR CORRECTING DISPLACEMENT OF MULTI CARD AND METHOD FOR TESTING CIRCUIT ELEMENT

(75) Inventor: Yasushi NATORI, Suwa (JP)

Correspondence Address: HARNESS, DICKEY & PIERCE, P.L.C., P.O. BOX 828, BLOOMFIELD HILLS, MI, 48303, US

(73) Assignee: SEIKO EPSON CORPORATION, Tokyo (JP)

(21) Appl. No.: 12/476,281

(22) Filed: Jun. 2, 2009

Related U.S. Application Data
(62) Division of application No. 12/145,580, filed on Jun. 25, 2008.

(30) Foreign Application Priority Data
Jul. 12, 2007 (JP) 2007-182885

(51) Int. Cl. G01R 31/02

(52) U.S. Cl. 324/758

(57) ABSTRACT

A method for correcting displacement of a multi card with respect to a product wafer, includes displacing a predetermined wafer on a stage of a probing device and forming a contact trace of a probe needle on a surface of the wafer by bringing the probe needle into contact with the wafer disposed on the stage; localizing, based on the contact trace, a displaced area from the surface of the wafer, the area being displaced with respect to the multi card, and determining a displacement amount of the displaced area; and setting a parameter based on the displacement amount, the parameter to be referred in the case of positioning of the multi card to the displaced area. The displacement of the multi card is corrected in a case of testing electric characteristics of a plurality of circuit elements formed on the product wafer with the use of the multi card capable of bringing the probe needles into contact with the plurality of circuit elements all at once.

This application is a divisional of U.S. patent application Ser. No. 12/145,580 filed on Jun. 25, 2008. This application claims the benefit of Japanese Patent Application No. 2007-182885 filed Jul. 12, 2007. The disclosures of the above applications are incorporated herein by reference.

### BACKGROUND OF THE INVENTION

1. Technical Field

The present invention relates to a method for correcting displacement of a multi card and a method for testing a circuit element.

2. Related Art

In a testing process of semiconductor devices, electric characteristics thereof are measured without dicing a plurality of IC chips formed on a wafer. To carry out this measurement, probe needles are brought into contact with pad electrodes of the IC chips, respectively. In the testing process of semiconductor devices, the electric characteristics are sometimes measured by regulating temperature of the IC chips at testing temperatures such as a low temperature of −45 degrees Celsius, a room temperature, and a high temperature of 125 degrees Celsius. Especially in the case of carrying out this measurement with the use of a probe card (hereinafter, referred to as a multi card), which enables measurement of the plurality of IC chips at the same time, it is highly important that the probe needle and the pad electrode are brought into contact at a precise position.

FIG. 6 is a schematic view for illustrating a testing method according to related arts and problems thereof. To achieve stable measurement, the probe needle and the pad electrode of the IC chip are placed in correct positions in a state that a multi card and a stage 91 of a probing device are heated enough in consideration of heat expansion thereof. This measurement is then started, in which the stage 91 is indexed in a direction of arrow in FIG. 6, for example. JP-A-2004-344498 and JP-A-2004-266206 are examples of related art.

When the measurement with the use of the multi card is carried out to a test subject area 93 located at a periphery of a wafer W′, a part of the multi card lies off the stage 91 of the probing device, so that a needle tip of the part that lies off the stage 91 is cooled down. Therefore, the next index has an increased possibility that a needle of the cooled part of the multi card is displaced, thereby leading to a risk that the probe needle cannot be brought into proper contact with a pad electrode 97, which causes a problem. This problem gradually becomes more obvious as the multi card grows in size and the amount that the multi card lies off the stage 91 increases.

As a solution for the above problems, in the case where the multi card lies off the stage 9, such a method has been proposed that the amount of displacement is measured by directly monitoring the probe needles with the use of a camera disposed outside the stage 9. In the next index, a position of the stage 91 is then corrected, namely, a needle alignment is performed, in a manner to cancel the displacement amount. By this method, however, it is necessary to separate the multi card from the stage 91 in order to monitor needle tips, during which the multi card is undesirably cooled down. Therefore, if the probe needles are brought into contact with the wafer after the needle alignment, the probe needles receive heat applied from the wafer, thereby raising the possibility that the needle tip is displaced.

### SUMMARY

An advantage of the present invention is to provide a method for correcting displacement of a multi card and a method for testing a circuit element that enable stable measurement by preventing faulty connection at the time of testing a product wafer.

According to a first aspect of the invention, a method for correcting displacement of a multi card with respect to a product wafer, includes displacing a predetermined wafer on a stage of a probing device and forming a contact trace of a probe needle on a surface of the wafer by bringing the probe needle into contact with the wafer disposed on the stage; localizing, based on the contact trace, a displaced area from the surface of the wafer, the area being displaced with respect to the multi card, and determining a displacement amount of the displaced area; and setting a parameter based on the displacement amount, the parameter to be referred in the case of positioning of the multi card to the displaced area. The displacement of the multi card is corrected in a case of testing electric characteristics of a plurality of circuit elements formed on the product wafer with the use of the multi card capable of bringing the probe needles into contact with the plurality of circuit elements all at once.

Here, either a correlation wafer, that is, a wafer for a test, or a product wafer may be used as the “predetermined wafer”. The “parameter” is stored in a memory device of the probing device such as a hard disk or a nonvolatile memory, for example. “Setting a parameter based on the displacement amount” means that the parameter is set so that the displacement amount approaches zero, for example.

It is preferable that the displaced area be localized at a periphery within the surface of the wafer during the localizing the displaced area based on the contact trace and that the periphery include a test subject area to be tested next with the use of the probe needle that lies off the stage.

Here, in the case of testing electric characteristics of the circuit elements formed on a periphery of the wafer, one part of the probe needles included in the multi card sometime lies off the stage without coming into contact with the wafer. According to the inventor of the present invention, when the probe needle lies off the stage, a temperature becomes different between this probe needle and the wafer disposed on the stage. For example, in a high-temperature test, when one part of the multi card lies off the stage, the needle tip of the part that lies off the stage is cooled down. In the test subject area to be tested next with the use of the cooled probe needle, displacement occurs between the probe needle and the circuit element. The amount of displacement, that is, the displacement amount, tends to increase as a temperature difference between the probe needle and the wafer increases.

It is preferable that the method for correcting displacement of a multi card further include adjusting each of temperatures of the wafer and the probe needle to a testing temperature before forming the contact trace by bringing the probe needle into contact with the surface of the wafer. Here, the “testing temperature” includes a low or high temperature. For example, a temperature of −45 degrees Celsius is a low temperature while 125 degrees Celsius is a high temperature.

According to a second aspect of the invention, a method for testing a circuit element includes testing electronic characteristics of the circuit elements formed on the product wafer after performing the method for correcting displacement of a multi card according to the first aspect of the invention.

According to the above aspects of the invention, the displacement amount of the multi card with respect to the product wafer is kept track for each test subject area and this amount can be canceled, thereby enabling stable measurement. Further, preliminary heating of the probe needle is no longer necessary. That us, the testing is no longer required to be interrupted to heat up the probe needle, so that shortening of the testing period can be expected and the testing efficiency can be improved.

According to a third aspect of the invention, a method for testing a circuit element includes readjusting a probe needle to a testing temperature before bringing the probe needle into contact with a next test subject area in a case where the probe needle lies off a stage in a state where a product wafer is disposed on the stage of the probe device and each of temperatures of the product wafer and the probe needle is adjusted to a testing temperature; and bringing the probe needle into contact with the next test subject area without readjusting the probe needle to the testing temperature in a case where the probe needle does not lie off the stage. Electric characteristics of a plurality of circuit elements formed on the product wafer are tested with the use of the multi card capable of bringing the probe needles into contact with the plurality of circuit elements all at once.

It is preferable that the probe needle be shifted to above a center of the product wafer and that the probe needle be left on standby in this position for a predetermined period to set a temperature of the probe needle close to the testing temperature in the case of readjusting a temperature of the probe needle to the testing temperature.

By the testing method according to the above aspects of the invention, a temperature of the probe needle can be readjusted only when there is the possibility of causing displacement due to fluctuation of this temperature from the testing temperature. In a test at the high temperature test, the preliminary heating is performed to the probe needle only when there is the possibility of causing the displacement due to cooling down of the probe needle. Therefore, the displacement can be prevented in advance to enable the stable measurement.

### BRIEF DESCRIPTION OF THE DRAWINGS

The invention will be described with reference to the accompanying drawings, wherein like numbers reference like elements.

FIG. 1 is a flowchart for explaining a method for correcting a position of a multi card according to a first embodiment;

FIG. 2 is a schematic view for showing a state at the time of positioning with a wafer W1;

FIGS. 3A and 3B are views each showing a correction table and an exemplary correction amount;

FIGS. 4A and 4B are schematic views each showing a state at the time of testing a wafer W2;

FIG. 5 is a schematic view for explaining a method for correcting a position of a multi card according to a second embodiment; and

FIG. 6 is a schematic view for explaining a testing method according to existing arts and a problem thereof.

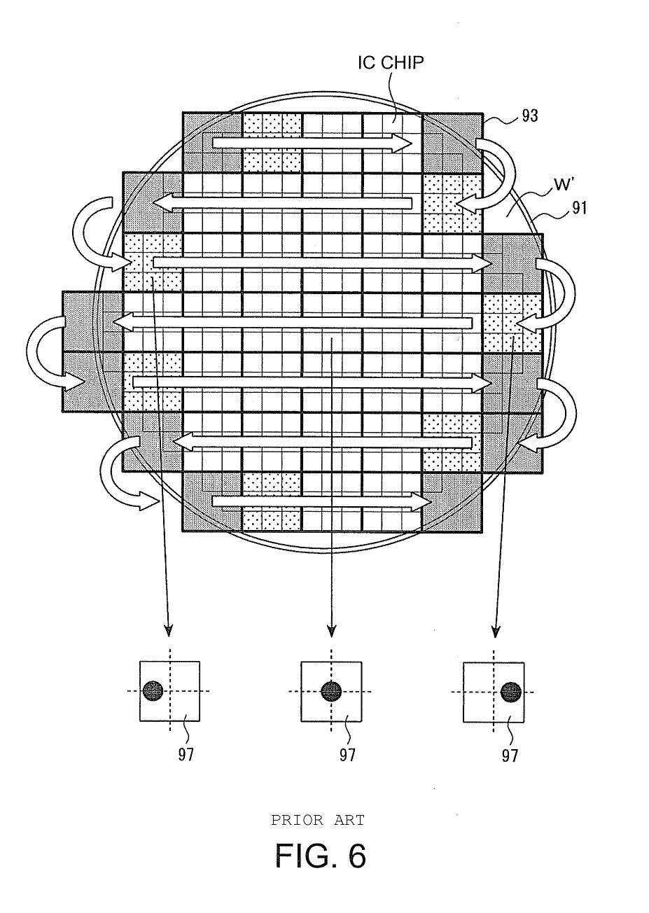

### DESCRIPTION OF EXEMPLARY EMBODIMENTS

Embodiments according to the present invention will be described hereinafter with reference to drawings.

### First Embodiment

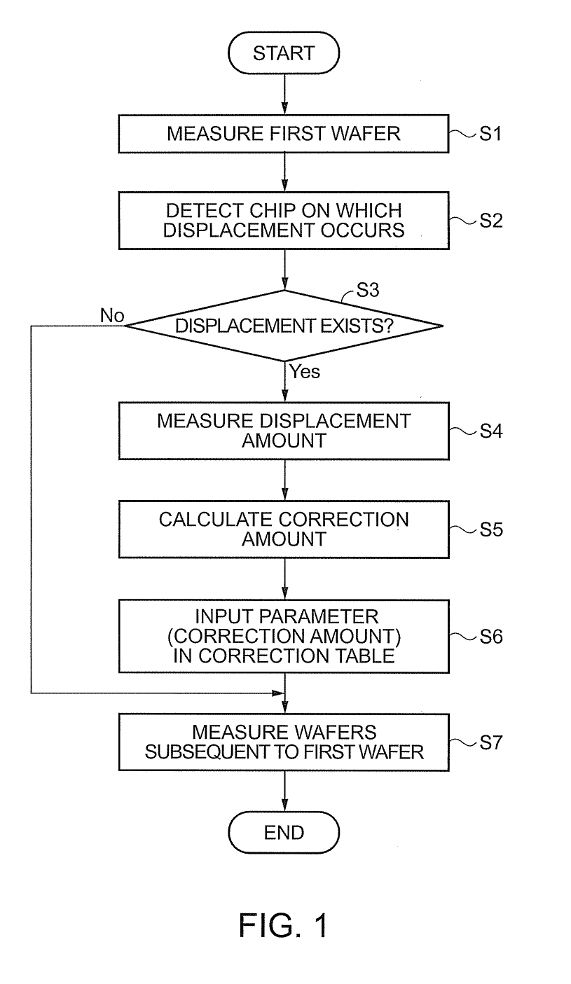

FIG. 1 is a flowchart showing a method for correcting a position of a multi card according to a first embodiment. Electric characteristics of IC chips formed on a wafer are measured by bringing probe needles and pad electrodes of the IC chips into contact with each other. This type of measurement adopts tests at a low temperature of −45 degrees Celsius, a room temperature, a high temperature of 125 degrees Celsius, and the like. Explained herein is a case where a test at a high temperature, that is, wafer-level burn-in is carried out with the use of the multi card.

At the step 1 in FIG. 1, for example, a correlation wafer or a product wafer referred to as a first wafer is used to place the probe needles and the pad electrodes of the IC chips in correct positions. Here, in consideration of heat expansion of a multi card and a stage of a probe device, the positioning between the probe needles and the pad electrodes of the IC chips is started after heating the wafer and the multi card enough with the stage with heating and cooling functions intervened therebetween to bring the wafer and the multi card at a stable temperature.

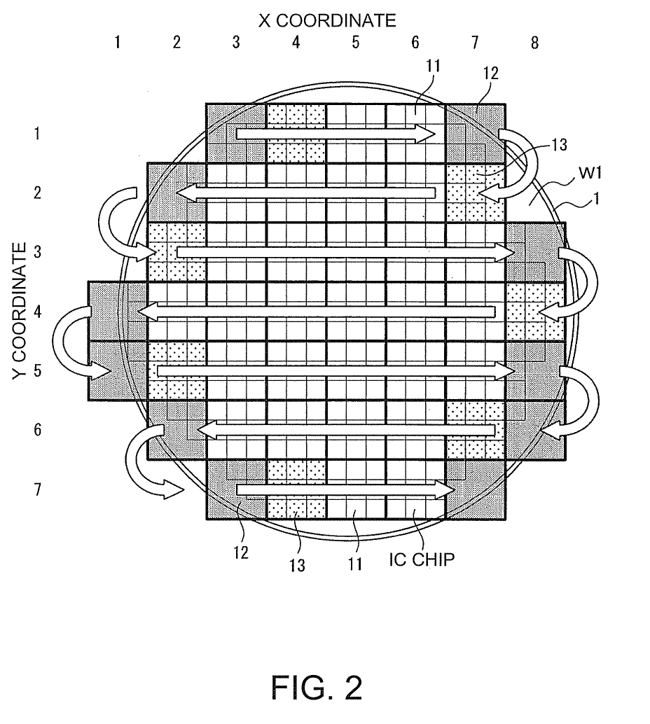

FIG. 2 is a schematic view for showing an index direction at the time of positioning with a first wafer W1 and a positional relationship among test subject areas 11, 12, 13 on the wafer W1. Surrounded by a heavy line, in FIG. 2, are the test subject areas 11, 12, 13 with which the multi card is brought into contact all at once. Arrows in FIG. 2 denotes the index direction. The index process is such that the multi card is shifted with respect to a stage 1 at regular intervals. The multi card and the stage 1 may be shifted relatively. In this case, the stage is shifted at regular intervals on a condition that the multi card is fixed.

Through the aforementioned index process, each of the test subject areas 11, 12, 13 is brought into contact with the multi card. However, one part of the multi card lies off the stage 1 of the probe device when a periphery of the wafer is subjected to the index process. In the test subject area 12 at which the multi card lies off the stage, the area being referred to as a multi-card-lying-off part, the probe needle of the part which lies off the stage is cooled down. As a result, displacement occurs between the probe needle and the pad electrode in the test subject area 13, which is brought into contact with this cooled needle tip next. In this test subject area 13 in which the displacement occurs, the area being referred to as a displaced area hereinafter, the probe needle is brought into contact with the wafer W1, thereby being heated up. Thus, the displacement due to decrease in temperature hardly occurs in the next test subject area 11.

Next, at the step S2 in FIG. 1, the IC chip on which the displacement occurs is detected on the first wafer W1. Here, a trace of contact between the pad electrode and the probe needle is observed with eyes to detect the IC chip referred to as a displacement chip hereinafter, in which the contact trace is off a center of the pad electrode. A judgment is then made at the step S3 in FIG. 1 as to whether the displacement chip exists or not. This judgment is made by, for example, an operator (person). In the case of existence of the displacement chip, the current step is moved to the process at the step S4. In the case of no displacement chip, the current step is moved to the process at the step S7. In this case where the displacement chip is detected in the displaced area 13 shown in FIG. 2, the step is moved to the process at the step S4 in FIG. 1.

At the step S4 in FIG. 1, the displacement amount in the displacement chip is measured. This measurement is curried out by, for example, the operator (person). At the step S5 in FIG. 1, the correction amount is calculated for each of the displaced areas 13 based on the measured displacement amount.

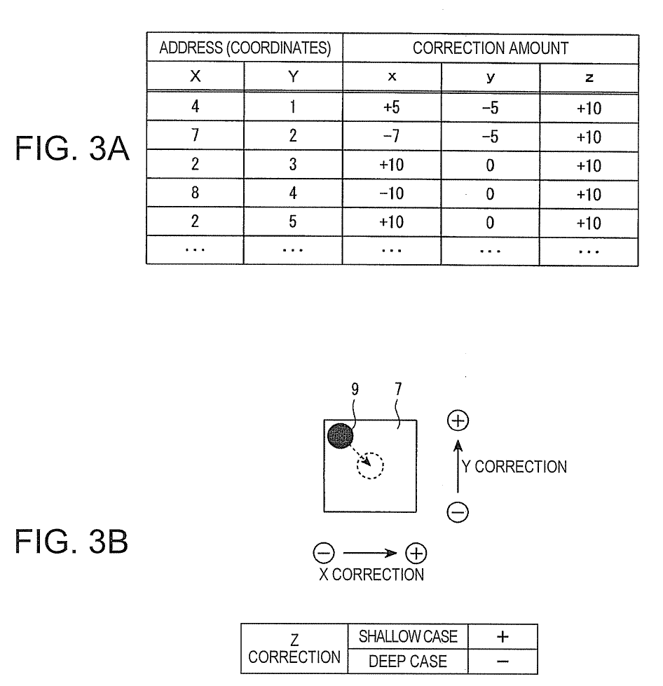

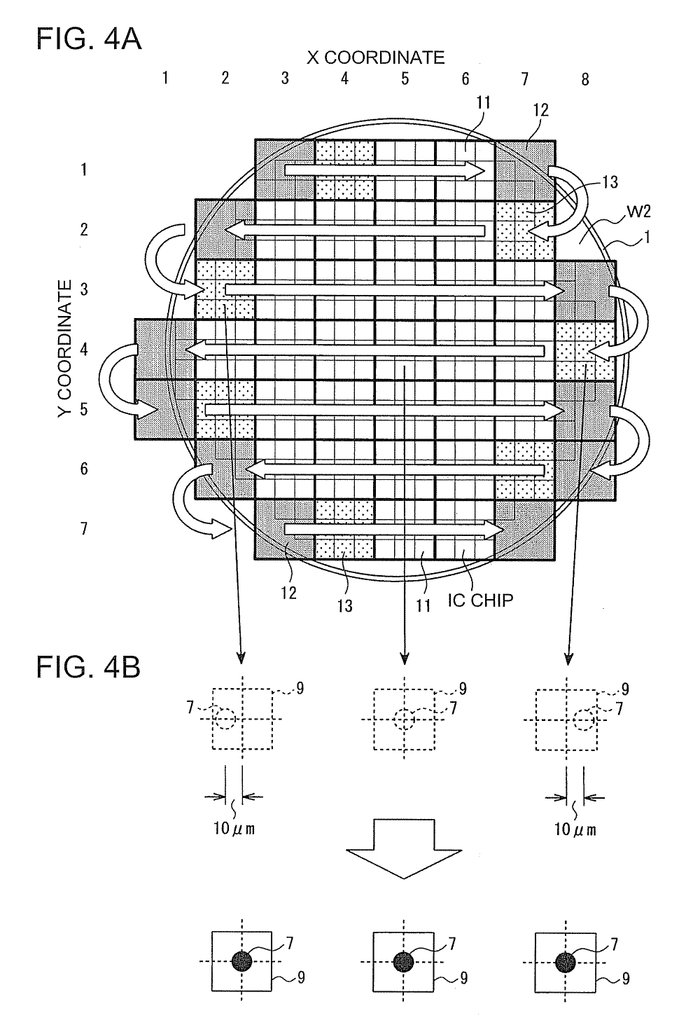

FIGS. 3A and 3B are views each showing a correction table and an exemplary correction amount. An address in FIG. 3A denotes coordinates (X, Y) of the test subject areas, which correspond to both X, Y coordinates in FIG. 2 and X, Y coordinates in FIG. 4A, respectively. In FIG. 3A, alphabets, x, y, and z, denote correction amounts in an x direction as a width direction, a y direction as a height direction, and a z direction as a breadth direction, respectively, in each address. In a case where, for example, as shown in FIG. 3B, a contact trace 9 is formed at not a center but an upper left of a pad electrode 7, correction of +5 in the x direction and −5 in the y direction, for example, is made to subsequent wafers in a manner to form this contact trace 9 at the center of the pad electrode 7. This correction amount is calculated for each displacement region. At the step S6 in FIG. 1, each calculated correction amounts is input as a positioning parameter in the correction table of the probe device. Those calculation and input operations are performed by the operator (person), for example. Thereafter, at the step S7 in FIG. 1, the subsequent wafers are tested with the use of the multi card. Those subsequent wafers are each a product wafer.

FIGS. 4A and 4B are schematic views each showing an index direction at the time of testing a second wafer W2 as the subsequent wafer and a positional relationship among the test subject areas 11, 12, 13 on the wafer W2. At the step S7, as shown in FIG. 4A, the second wafer W2 is disposed on the stage 1. The stage 1 is then indexed in the same order as that of the first wafer to test a plurality of circuit elements with the use of the multi card all at once. In testing this second wafer, the position of the stage 1 is corrected based on the parameter input in the correction table.

Specifically, with respect to the test subject area with an address of (X, Y)=(2, 3) as shown in FIG. 4B, for example, at which the displacement amount in the x direction of −10 μm occurs on the first wafer, the displacement amount in the x direction is set to 0 μm on the second wafer W2 by inputting the correction amount x equal to +10 in the correction table (see, FIG. 3A). Furthermore, with the test subject area with an address of (X, Y)=(8, 4), at which the displacement amount in the x direction of +10 μm occurs on the first wafer, the displacement amount in the x direction is set to 0 μm on the second wafer W2 by inputting the correction amount x equal to −10 in the correction table (see, FIG. 3A).

Subsequent to testing the wafer W2, the multi card is brought into contact with the subsequent wafers in numeric order from the third wafer, thereby testing electric characteristics of the IC chips. At this time, the correction amount has already been input in the correction table, so that the displacement of the multi card can be corrected in a manner similar to that when testing the second wafer W2.

As described above, according to the first embodiment, the displacement amount of the multi card is kept track for each of the test subject areas 11, 12, 13 within a surface of the wafer W1. At the time of testing the second wafer W2, the position of the stage 1 is corrected so as to cancel the displacement amount having been kept track at the time of testing the wafer W1. In this manner, the probe needles can be prevented from being displaced with respect to the pad electrodes of the IC chips, which enables stable measurement. Further, the preliminary heating of the probe needle is no longer necessary. That is, the testing is no longer required to be interrupted to heat up the probe needle, so that shortening of the testing period can be expected and the testing efficiency can be improved.

In the first embodiment described above, a case has been explained that the process from the step S2 to the step S6 is conducted by hand, that is, conducted directly by the operator (person). However, the process at all steps including the step S2 through S6 in FIG. 1 may be automatically performed by the probe device in this invention. Specifically, after measuring the first wafer automatically at the step S1 in FIG. 1, the probe device observes the surface of the wafer with the use of the camera at the step S2 to automatically detect the chip on which the displacement occurs. Subsequently, the probe device automatically makes a judgment at the step S3 as to whether the displacement occurs or not. In the event of the displacement, the probe device automatically calculates the displacement amount at the step S4. At the step S5 in FIG. 1, the probe device automatically calculates the displacement amount as a parameter, thereby inputting this parameter into the correction table automatically at the step S6. Thereafter, the probe device automatically measures the wafers subsequent to the first wafer. With this structure, the displacement of the multi card is automatically corrected, which decreases burden on the operator (person).

With respect to the wafers subsequent to the first wafer, the correct amount may be reviewed by performing the process from the step 1 to the step S7 at certain time intervals, on a certain amount basis, or per contact. This structure contributes improvement in the contact precise of the multi card to the wafer.

In the first embodiment described above, a case has been explained that the IC chip on which the displacement occurs is detected on the wafer surface at the step S2 in FIG. 1. However, as shown in FIGS. 2 and 4, in the case of the index process in a traversal manner, there is the little possibility of causing the displacement in the test subject areas 11, 12 due to decrease in temperature. Therefore, at the step S2 in FIG. 1, only the displaced area 13 is focused on so that the displacement chip is detected within the area 13. With this structure, the time required to localize the displacement chip can be shortened.

### Second Embodiment

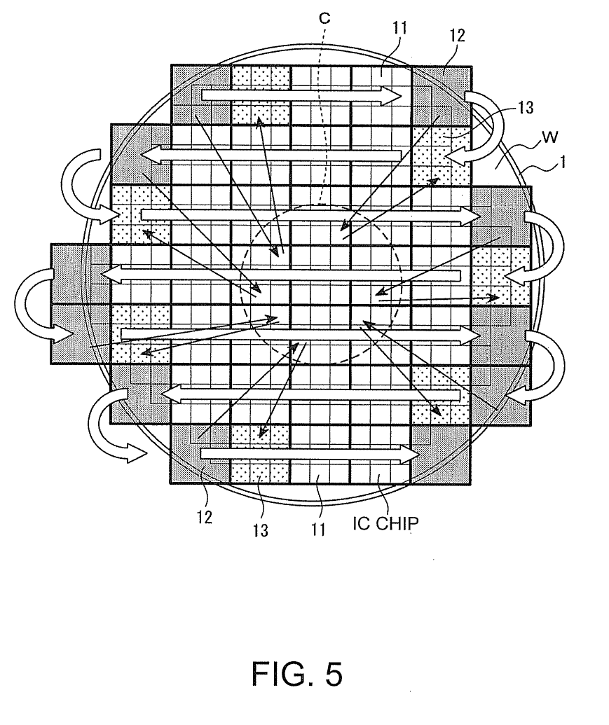

FIG. 5 is a schematic view showing a method for correcting a position of a multi card according to a second embodiment of this invention. In FIG. 5, the part identical to that in FIG. 4 is assigned with the same reference and detailed explanation thereof is omitted. Explained herein is a case where a test at a high temperature, that is, wafer-level burn-in is carried out with the use of the multi card.

As shown in FIG. 5, each of the test subject areas 11, 12, 13 is brought into contact with the multi card. In the second embodiment, after testing a multi-card-lying-off part 12, the multi card is shifted to an upper side of a center C of the wafer W2 and then left on standby for a certain time. At this time, the probe needle of the multi card is not brought into contact with the wafer W2 and a slight gap is formed between the probe needle and the wafer W2. Therefore, the temperature of the cooled probe needle can be adjusted so as to approach the temperature of the high-temperature test (for example, 125 degrees Celsius). Formation of the above gap can prevent a surface of the center C from being damaged.

Next, the displaced area 13 is tested by shifting the multi card from the upper side of the center C to the displaced area 13. The probe needle is heated up at the upper side of the center C of the wafer W2, and is brought to the displaced area 13 through the upper side of the wafer W2 during shifting, so that the probe needle is kept warm. Therefore, the displacement due to decrease in temperature can be prevented during the test of the displaced area 13. In the case of the index process in a traversal manner, there is the little possibility of causing the displacement on the test subject areas 11, 12 due to decrease in temperature. Therefore, after testing the multi-card-lying-off area 12, the multi card is shifted to the upper side of the center C of the wafer W2 before testing the displaced area 13, thereby readjusting the temperature of the probe needle. Other than this case, the multi card is shifted to the next test subject areas 11, 12 without readjustment of the temperature of the probe needle.

In this manner, according to the second embodiment of this invention, the preliminary heating is performed to the probe needle only when there is the possibility of causing the displacement due to cooling down of the probe needle. Therefore, the displacement can be prevented in advance, which achieves the stable measurement.

In the above first and second embodiments, the wafer W2 corresponds to a “product wafer” in this invention and the IC chip corresponds to a “circuit element”. The wafer W1 corresponds to a “predetermined wafer” in this invention and the correction amount shown in FIG. 3A corresponds to a “parameter” in this invention. Further, the displaced area 13 corresponds to a “test subject area to be tested next with the use of the probe needle that lies off the stage” in this invention.

What is claimed is:

1. A method for testing a circuit element, comprising;
readjusting a probe needle to a testing temperature before bringing the probe needle into contact with a next test subject area in a case where the probe needle lies off a stage in a state where a product wafer is disposed on the stage of a probing device and each of temperatures of the product wafer and the probe needle is adjusted to a testing temperature; and
bringing the probe needle into contact with the next test subject area without readjusting the probe needle to the testing temperature in a case where the probe needle does not lie off the stage, wherein:
electric characteristics of a plurality of circuit elements formed on the product wafer are tested with the use of the multi card capable of bringing the probe needles into contact with the plurality of circuit elements all at once.

2. The method for testing a circuit element according to claim 1, wherein the probe needle is shifted above a center of the product wafer and in this position, the probe needle is left on standby for a predetermined period to set a temperature of the probe needle close to the testing temperature in the case of readjusting a temperature of the probe needle to the testing temperature.
